(19) United States
(12) Patent Application Publication
(10) Pub. No.: US 2022/0165605 A1
(43) Pub. Date: May 26, 2022

(54) DEVICE FOR INSPECTING FOR COLOR UNEVENNESS IN FLEXIBLE DISPLAY

(71) Applicant: SAKAI DISPLAY PRODUCTS CORPORATION, Sakai-shi, Osaka (JP)

(72) Inventors: KATSUHIKO KISHIMOTO, Sakai-shi, Osaka (JP); Yoshitaka KITAMURA, Sakai-shi, Osaka (JP)

(21) Appl. No.: 17/602,506

(22) PCT Filed: Apr. 10, 2019
(86) PCT No.: PCT/JP2019/015646

§ 371 Date: Oct. 8, 2021

(51) Int. Cl. H01L 21/683; B25B 11/00

(52) U.S. Cl. CPC H01L 21/6838; B25B 11/005

(57) ABSTRACT

A color unevenness inspection system (100) of the present disclosure includes: an inspection stage (20) on which a flexible display (10) including a flexible substrate (12) is to be placed, the inspection stage (20) having a vacuum chuck surface (22); and a porous sheet (30) placed on the vacuum chuck surface (22) , the porous sheet being to be in contact with a lower surface of the flexible substrate (12). The porous sheet (30) has a plurality of pores for sucking in a single or a plurality of foreign objects (60) adhered to the lower surface of the flexible substrate (12) such that flatness of the lower surface is maintained.

### TECHNICAL FIELD

The present disclosure relates to a color unevenness inspection system for flexible displays.

### BACKGROUND ART

A typical example of the flexible display includes a film which is made of a synthetic resin such as polyimide (hereinafter, referred to as “plastic film”), and elements supported by the plastic film, such as TFTs (Thin Film Transistors) and OLEDs (Organic Light Emitting Diodes). The plastic film functions as a flexible substrate. The flexible display is encapsulated with a gas barrier film (encapsulation film) because organic semiconductor layers which are constituents of the OLED are likely to deteriorate due to water vapor.

In production of flexible displays, an inspection step is performed for finally detecting display abnormalities. The display abnormalities include defective pixel, abnormal pixel size, abnormal luminance, and color unevenness. Such an inspection is performed on a flexible device placed on a stage of an inspection system.

Japanese Laid-Open Patent Publication No. 2010-151527 discloses a system for performing an inspection for display unevenness which can occur in flat panel displays such as liquid crystal display devices and organic electroluminescence display devices.

### CITATION LIST

### Patent Literature

Patent Document No. 1: Japanese Laid-Open Patent Publication No. 2010-151527

### SUMMARY OF INVENTION

### Technical Problem

When a flexible display is inspected for color unevenness using a conventional inspection system, the conventional inspection system can erroneously detect color unevenness even though no color unevenness occurs in the display under inspection. If there is even a small probability of such an erroneous detection, it is necessary to perform a re-inspection on all products in which color unevenness is detected.

The present disclosure provides a color unevenness inspection system for flexible devices which can solve the above-described problems.

### Solution to Problem

A color unevenness inspection system of the present disclosure is, in an exemplary embodiment, a color unevenness inspection system for inspecting a flexible display for color unevenness, the system including: an inspection stage on which a flexible display including a flexible substrate is to be placed, the inspection stage having a vacuum chuck surface; and a porous sheet placed on the vacuum chuck surface, the porous sheet being to be in contact with a lower surface of the flexible substrate. The porous sheet has a plurality of pores for sucking in a single or a plurality of foreign objects at the lower surface of the flexible substrate such that flatness of the lower surface is maintained.

In one embodiment, a porosity of the porous sheet is not less than 50%, and a thickness of the porous sheet is not less than three times a height of the foreign object.

In one embodiment, the thickness of the porous sheet is not less than 50 μm and not more than 5 mm.

In one embodiment, the porous sheet is a sheet including a single or a plurality of layers of woven fiber and/or knitted fiber.

In one embodiment, the porous sheet is a film containing a plurality of organic fillers and a resin which binds the plurality of organic fillers.

In one embodiment, the color unevenness inspection system includes an electrical conductor layer of not less than 5 nm and not more than 20 nm in thickness over a surface.

In one embodiment, the porous sheet is replaceably supported on the vacuum chuck surface of the inspection stage.

In one embodiment, a breathable adhesive layer is provided between the porous sheet and the vacuum chuck surface.

In one embodiment, the porous sheet includes the breathable adhesive layer that is in contact with the vacuum chuck surface.

In one embodiment, the breathable adhesive layer is located between at least part of the porous sheet on which the flexible display is to be placed and the vacuum chuck surface.

In one embodiment, an average pore diameter of the porous sheet is not more than 2 μm.

### Advantageous Effects of Invention

According to an embodiment of the present invention, a novel color unevenness inspection system for flexible devices is provided which can solve the above-described problems.

### BRIEF DESCRIPTION OF DRAWINGS

FIG. 1 is a perspective view schematically showing a configuration example of a color unevenness inspection system 100 of an embodiment of the present disclosure.

FIG. 2 is an enlarged cross-sectional view schematically showing part of the color unevenness inspection system 100.

FIG. 3 is a perspective view schematically showing a configuration example of a color unevenness inspection system 200 of a comparative example.

FIG. 4 is an enlarged cross-sectional view schematically showing part of the color unevenness inspection system 200.

FIG. 5 is a cross-sectional view illustrating the mechanism of an erroneous detection of color unevenness.

FIG. 6 is a cross-sectional view showing parameters regarding a porous sheet 30 which can be used in an embodiment of the present disclosure.

FIG. 7 is a cross-sectional view schematically showing a porous sheet 30A which can be used in an embodiment of the present disclosure.

FIG. 8 is a cross-sectional view schematically showing a porous sheet 30B which can be used in an embodiment of the present disclosure.

### DESCRIPTION OF EMBODIMENTS

Prior to the description of embodiments of the present disclosure, the knowledge and technological background acquired by the present inventors are described.

As previously described, when a flexible display is inspected for color unevenness using a conventional inspection system, the conventional inspection system can erroneously detect color unevenness even though no color unevenness occurs in the display under inspection. The present inventors conducted research and found that the cause of the erroneous detection was a microparticle or dust taken into the interface between the flexible display and an inspection stage.

Herein, such a microparticle and dust are generically referred to as “foreign object”. A typical example of the foreign object is a foreign object called “particle”, and it can be made of various materials (organic substances and/or inorganic substances). Foreign objects such as particles are, in many cases, derived from substances adhered to a carrier or the like or substances floating in the air. Some of such foreign objects are adhered to the flexible substrate or present on the upper surface of the inspection stage. When there is a foreign object adhered to the upper surface of the inspection stage, inspection of a plurality of flexible displays results in that color unevenness occurs at the same position in every one of the flexible displays.

When the substrate is made of a material of high hardness such as a glass substrate, a local deformation is unlikely to occur in the substrate even if such a foreign object is present between the stage and the display. As a result, detection of color unevenness attributable to the foreign object is avoided. However, according to experiments by the present inventors, it was found that, in the case of a flexible display, even a small foreign object can cause the flexible substrate to locally deform, and the deformation can cause color unevenness. The mechanism of occurrence of color unevenness attributable to a foreign object will be described later.

It was also found that such color unevenness attributable to a foreign object can be restored to a normal display state by displacing the flexible display from the inspection stage and performing a simple cleaning to remove the foreign object. That is, the color unevenness attributable to the foreign object does not indicate an essential defect in the product but can be said to be an erroneous detection of color unevenness.

It is ideal to thoroughly remove the presence of such a foreign object before performing the inspection, although this is actually difficult. The color unevenness inspection system of the present disclosure is capable of suppressing or preventing an erroneous detection of color unevenness even if such a foreign object is present.

Hereinafter, an embodiment of a color unevenness inspection system for flexible devices according to the present disclosure is described with reference to the drawings. In the following description, unnecessarily detailed description will be omitted. For example, detailed description of well-known matter and repetitive description of substantially identical elements will be omitted. This is for the purpose of avoiding the following description from being unnecessarily redundant and assisting those skilled in the art to easily understand the description. The present inventors provide the attached drawings and the following description for the purpose of assisting those skilled in the art to fully understand the present disclosure. Providing these drawings and description does not intend to limit the subject matter recited in the claims.

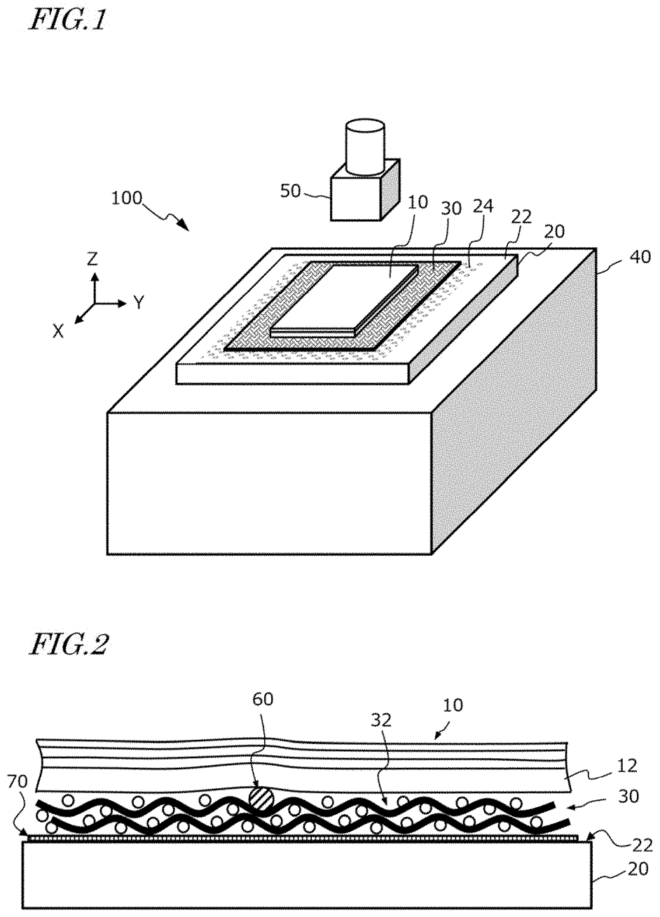

Firstly, refer to FIG. 1 and FIG. 2. FIG. 1 is a perspective view schematically showing a configuration example of a color unevenness inspection system 100 of an embodiment of the present disclosure. FIG. 2 is an enlarged cross-sectional view schematically showing part of the color unevenness inspection system 100. In FIG. 1, X-axis, Y-axis, and Z-axis which are perpendicular to one another are schematically shown for reference.

The color unevenness inspection system 100 is a system for inspecting a flexible display 10 for color unevenness (inspection system). The flexible display 10, which is a subject of the inspection, includes a flexible substrate 12 and an array of elements (not shown), such as TFTs and OLEDs, supported by the flexible substrate 12. As previously described, organic semiconductor layers which are constituents of OLEDs are likely to deteriorate due to water vapor. Therefore, when the flexible display 10 includes an array of OLEDs, the flexible display 10 is encapsulated with a gas barrier film. Note that the flexible display 10 does not need to be a device including OLEDs but may include an array of any other type of light-emitting devices, for example, μLEDs including inorganic semiconductors.

The color unevenness inspection system 100 includes an inspection stage 20 on which a flexible display 10 is to be placed. The inspection stage 20 has a vacuum chuck surface 22 and is provided on a supporting base 40. The inspection stage 20 may be supported so as to be movable across the XY plane on the supporting base 40. In that case, the inspection stage 20 can be positioned with high accuracy using an actuator such as motor.

The vacuum chuck surface 22 has a large number of holes which are in communication with hollows inside the inspection stage 20. When the inside of the inspection stage 20 is decompressed to a negative pressure by an unshown decompression pump or the like, outside air flows in through the large number of holes 24 of the vacuum chuck surface 22 so that an object which is in contact with the vacuum chuck surface 22 can be held by suction. The vacuum chuck surface 22 is flat and can be made of a rigid material, for example, a porous ceramic material.

The color unevenness inspection system 100 includes an imaging unit 50 for taking displayed images on the flexible display 10 and an unshown image processing unit for processing image data taken by the imaging unit 50. The imaging unit includes an image sensor and is capable of taking displayed images on the flexible display 10 at an arbitrary angle. The image processing unit may be realized by, for example, a digital signal processor (DSP), a programmable logic device (PLD) such as field programmable gate array (FPGA), or a combination of a central processing unit (CPU), or a graphical processing unit (GPU), and computer programs.

In the present embodiment, the color unevenness inspection system 100 further includes a porous sheet 30 provided on the vacuum chuck surface 22. The porous sheet 30 is located at such a position that, when a flexible display 10 under inspection is placed on the inspection stage 20, the porous sheet 30 is in contact with the lower surface of the flexible substrate 12. The porous sheet 30 is replaceably supported on the vacuum chuck surface 22 of the inspection stage 20. In a preferred embodiment, the porous sheet 30 includes an adhesive layer which is in contact with the vacuum chuck surface 22. This adhesive layer is capable of temporarily fixing the porous sheet 30 to the vacuum chuck surface 22 and, when necessary, easily pulling away the porous sheet 30 from the vacuum chuck surface 22. Also, this adhesive layer is breathable. Note that, however, the entirety of the adhesive layer does not need to be uniformly breathable. The breathability of the adhesive layer can be such that a vacuum chuck via the porous sheet 30 is realized and the flexible display 10 under inspection can be held by suction. Examples of the breathable adhesive layer include an adhesive sheet having a mesh structure and an adhesive sheet having a plurality of periodically-, nonperiodically-, or irregularly-arranged openings. Each of such a plurality of openings can have various shapes, such as circular, elliptical, rectangular, and polygonal shapes. The adhesive sheet having a plurality of openings may have, for example, a lattice shape where a plurality of stripes extending in row and column directions intersect with one another or may have the shape of a single stripe extending in a row or column direction.

As shown in FIG. 2, the porous sheet 30 has a plurality of the pores 32 for sucking in a single or a plurality of foreign objects at the lower surface of the flexible substrate 12 such that flatness of the lower surface can be maintained. The flatness can be maintained such that erroneous detection of color unevenness attributable to a foreign object can be suppressed. The foreign object 60 may be a foreign object adhered to the lower surface of the flexible substrate 12 or may be a foreign object which is present or comes in between the flexible substrate 12 and the porous sheet 30 when the flexible display 10 is placed on the inspection stage 20.

The large number of pores 32 of the porous sheet 30 also performs the function of transmitting the suction force of the vacuum chuck surface 22 in the lower layer to the flexible substrate 12 in the upper layer. Specifically, the pores 32 maintain and transmit a pressure-reduced state produced by the vacuum chuck surface 22 and function such that the vacuum chuck surface 22 sucks the flexible substrate 12. Many of the pores 32 of the porous sheet 30 allow communication from the upper surface to the lower surface of the porous sheet 30, although all of the pores 32 do not need to do so.

In the example shown in FIG. 2, a breathable adhesive layer 70 is provided between the vacuum chuck surface 22 of the inspection stage 20 and the porous sheet 30. The breathable adhesive layer 70 can have an arbitrary configuration and size which can enable the function of securing the porous sheet 30 to flat part of the vacuum chuck surface 22 while allowing the suction via the holes 24 of the vacuum chuck surface 22 to act on the porous sheet 30. The thus-configured breathable adhesive layer 70 desirably extends across the entirety of the gap between the porous sheet 30 and the vacuum chuck surface 22 but may be present in a selected partial region. The “selected partial region” refers to, for example, some parts or the entirety of a peripheral region of the porous sheet 30. Particularly, for preventing the flexure of the porous sheet 30 from affecting the color unevenness inspection, it is desirable that the breathable adhesive layer 70 is located between at least part of the porous sheet 30 on which the flexible display 10 is to be placed and the vacuum chuck surface 22. The thickness of the breathable adhesive layer 70 can be, for example, not less than 50 μm and not more than 250 μm. Using the thus-configured breathable adhesive layer 70 improves the flatness of the porous sheet 30 on the vacuum chuck surface 22 and enables more accurate color unevenness measurement.

Now, the configuration of a color unevenness inspection system 200 of a comparative example is described.

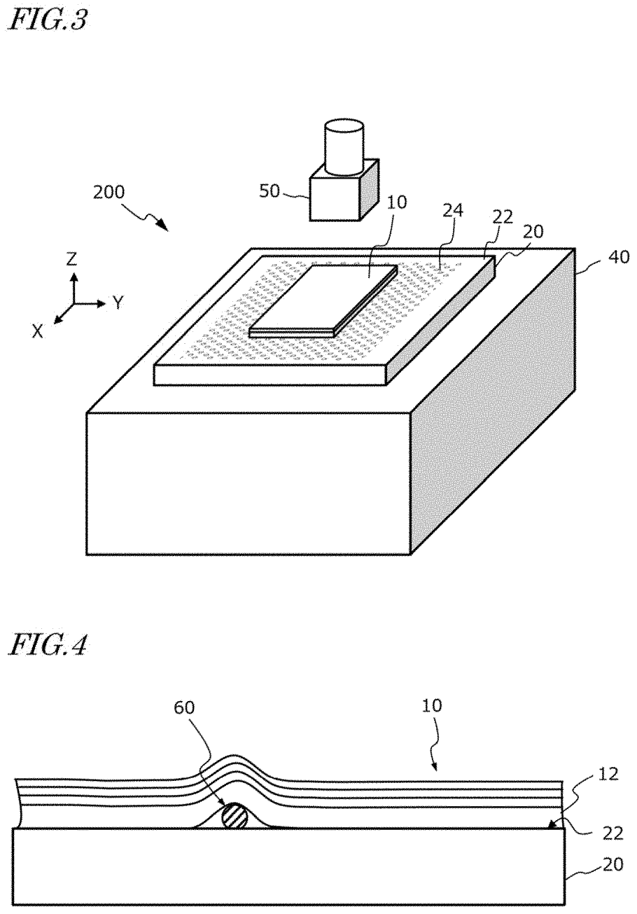

Firstly, refer to FIG. 3 and FIG. 4. FIG. 3 is a perspective view schematically showing a configuration example of the color unevenness inspection system 200 of a comparative example. FIG. 4 is an enlarged cross-sectional view schematically showing part of the color unevenness inspection system 200.

The color unevenness inspection system 200 has the same configuration as the color unevenness inspection system 100 illustrated in FIG. 1 except that the system 200 does not include the porous sheet 30. In the color unevenness inspection system 200, the flexible display 10 is directly placed on the vacuum chuck surface 22 of the inspection stage 20. Thus, as shown in FIG. 4, if there is a foreign object between the flexible substrate 12 of the flexible display 10 and the vacuum chuck surface 22 of the inspection stage 20, the foreign object 60 locally deforms the flexible display 10. Such a local deformation causes color unevenness in the inspection.

Next, the mechanism of occurrence of color unevenness attributable to the foreign object 60 is described with reference to FIG. 5. In FIG. 5, X-axis, Y-axis and Z-axis which are perpendicular to one another are schematically shown for reference. The imaging unit 50 is located in front of the vacuum chuck surface 22 of the inspection stage 20. Herein, the vacuum chuck surface 22 is parallel to the XY plane.

In the example of FIG. 5, the foreign object 60 is present between the flexible substrate 12 and the inspection stage 20. It is assumed that, in the inspection, desired emission of light comes out from the flexible display 10 by the units of pixels. In the example of FIG. 5, it is assumed that the foreign object 60 is present in a region of a red pixel, while no foreign object is present in a pixel region of a different color (e.g., blue) which is neighboring the red pixel. At the position where the foreign object 60 is present, the flexible display 10 is locally flexed. Basically, the luminance is highest when the flexible display 10 is viewed from the front direction of the vacuum chuck surface 22 (the normal direction of the vacuum chuck surface 22), and light radiated from pixels of the other colors are mixed, whereby the chromaticity is optimized. Particularly when the flexible display 10 is a device which includes OLEDs of a microcavity structure or when the flexible display 10 includes a μLED array with a microlens, the radiation intensity in the front direction is maximized in each pixel. However, as a result of the flexure caused by the foreign object 60, the directivity pattern of emission deforms. As a result, a light beam traveling from the red pixel to the front locally reduces and causes color unevenness. In FIG. 5, a representative example of light rays radiated from a red pixel is schematically illustrated by arrows R0, and a representative example of light rays radiated from a blue pixel is schematically illustrated by arrows B0. The radiation intensity of the flexible display 10 is greatest in the layer stacking direction of the emission layer. When the flexible display 10 is curved, the layer stacking direction of the emission layer is inclined with respect to Z-axis. Herein, this inclination angle is represented by e. In the example of FIG. 5, the red pixel is locally curved due to the foreign object 60. In the vicinity of the foreign object 60, the intensity of light rays traveling in the positive direction of Z-axis (arrows R1) decreases to case times the intensity of light rays (arrows R0). Therefore, the distribution of the radiation intensity in the vicinity of the foreign object 60 becomes nonuniform. Such a phenomenon that the Z-axis component of the radiation intensity is nonuniform due to the foreign object 60 would not occur in a portion where no foreign object is present and the flatness is maintained. Thus, the intensity of light rays schematically illustrated by arrows B1 of FIG. 5 is generally uniform as well as the intensity of light rays schematically illustrated by arrows B0.

For the above-described reasons, image processing performed based on image data taken by the imaging unit 50 located in front of the vacuum chuck surface 22 results in detection of color unevenness in a region where the foreign object 60 is present. In this example, there is no defect in a pixel in which the color unevenness is detected, and the flexible display 10 is not a defective product.

In assembling the flexible display 10 into other parts after the inspection, the foreign object 60 is removed from the flexible substrate 12 by a cleaning step or the like or remains on the vacuum chuck surface 22 of the inspection stage 20. Thus, erroneous detection of color unevenness attributable to the foreign object 60 leads to treating an actually normal flexible display 10 as a defective product.

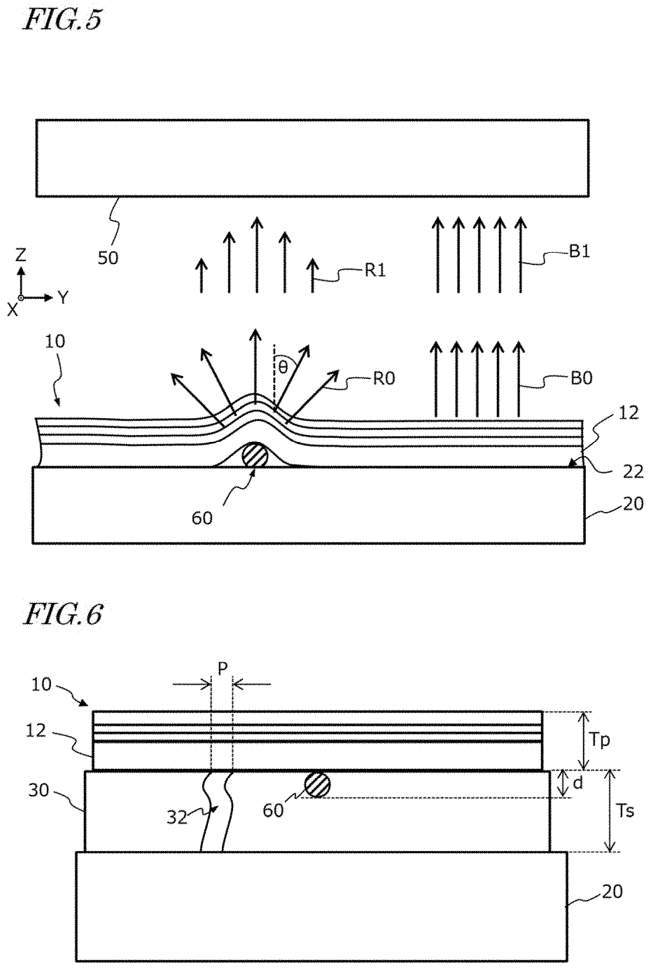

According to experiments by the present inventors, it was found that the degree of the effects of the foreign object on the causes of occurrence of color unevenness depends on the thickness of the flexible substrate 12. It was also found that the thickness and average pore diameter of the porous sheet 30 which are required for sucking in the foreign object and suppressing color unevenness also depend on the size of the foreign object and the thickness of the flexible display. This point will be described with reference to FIG. 6 in the following paragraphs.

FIG. 6 is a cross-sectional view showing parameters regarding a porous sheet 30 which can be used in an embodiment of the present disclosure. FIG. 6 schematically shows a foreign object 60 taken into the porous sheet 30 and a pore 32 which allows communication between the upper and lower surfaces of the porous sheet 30. Although the number of foreign objects 60 is not limited to one and the number of pores 32 is so many, FIG. 6 schematically shows only a single foreign object 60 and a single pore 32 from the viewpoint of visibility.

Herein, d is the size (diameter or height) of the foreign object 60, Tp is the thickness of the flexible display, Ts is the thickness of the porous sheet 30, and P is the average pore diameter of the pores 32 of the porous sheet 30. The size d of the foreign object 60 affects the thickness Ts and the porosity of the porous sheet 30 as will be described later. Therefore, the thickness Ts and the porosity of the porous sheet 30 are determined in consideration of an expected foreign object 60. Specifically, the thickness Ts of the porous sheet 30 places the upper limit on the largeness of the foreign object 60 that the porous sheet 30 can suck in. Also, the porosity of the porous sheet 30 affects the flexibility of the porous sheet 30 and affects whether or not the porous sheet 30 can suck in the foreign object 60.

The thickness Tp of the flexible display 10 that is a subject of the inspection affects the degree of local deformation in the flexible display 10 which is attributable to the foreign object 60. In general, as the thickness Tp of the flexible display 10 decreases, the rigidity decreases so that color unevenness is likely to occur due to the foreign object 60. Thus, the size d of the foreign object 60 that matters is determined in consideration of the thickness Tp of the flexible display 10 that is a subject of the inspection, and the thickness Ts and the porosity of the porous sheet 30 can be determined based on the determined size d.

If the average pore diameter P of the pores 32 of the porous sheet 30 is excessively large, there is a probability that the flexible display 10 will be flexed by vacuum suction even through there is no foreign object 60.

The present inventors performed experiments as to the above-described parameters. Hereinafter, findings from the results of the experiments will be described.

If the size d of the foreign object 60 is sufficiently small, the size d will not be a cause of color unevenness. The size d of the foreign object 60 which can be a cause of color unevenness roughly depends on the flexibility of the flexible display 10, i.e., thickness Tp. The thickness Tp of a usual flexible display 10 is within the range of, for example, not less than 30 μm and not more than 300 μm. When the flexible display 10 includes only a basic structure which includes a TFT layer, an OLED layer and an encapsulation layer on the flexible substrate 12, the thickness Tp is about 30 μm. On the other hand, the flexible display 10 includes, in addition to the basic structure, a heat dissipation sheet on the rear surface of the flexible substrate 12 and a touch panel layer and a polarizer on the encapsulation layer, the thickness Tp reaches about 300 μm. When the thickness Tp is 30 μm, the size d of the foreign object 60 can be a cause of color unevenness even if the size d is 0.15 μm. On the other hand, when the thickness Tp is 300 μm, color unevenness is nonnegligible so long as the size d of the foreign object 60 is not less than 1 μm.

If the flexible display 10 is thin and flexible and the average pore diameter P of the pores 32 of the porous sheet 30 is excessively large, there is a probability that vacuum suction will locally flex the flexible display 10 in the portions of the pores 32. This can cause another type of color unevenness which is different from the color unevenness attributable to the foreign object 60. If the average pore diameter P of the pores 32 is about 1/15 of the thickness Tp of the flexible display 10, there is a probability that portions of the respective pores 32 will flex. When the lower limit of the thickness Tp of the flexible display 10 that is a subject of the inspection is 30 μm, the average pore diameter of the porous sheet 30 is desirably not more than 2 μm.

The thickness Ts of the porous sheet 30 is desirably such a thickness that the foreign object 60 can be thoroughly buried in the porous sheet 30. Specifically, the thickness T is desirably not less than three times the size d of the foreign object 60. When the inspection is repeatedly performed using the same porous sheet 30, it is desirable that the thickness Ts of the porous sheet 30 is sufficiently greater than the foreign object 60. Thus, the thickness Ts of the porous sheet 30 is, for example, not less than 50 μm and not more than 5 mm. In consideration of easy detachment, the thickness Ts of the porous sheet 30 can be, for example, not less than 500 μm and not more than 2 mm.

If the porosity of the porous sheet 30 is not less than 50%, the foreign object 60 can be taken into the porous sheet 30 no matter in which portion of the porous sheet 30 the foreign object 60 is present. If the porosity is small, it is sometimes difficult to thoroughly bury the foreign object 60 which comes into contact with the porous sheet 30. According to calculations by the present inventors, the porosity is desirably not less than (5d)/(6Ts).

In the example of FIG. 2, the porous sheet 30 is a sheet including a single or a plurality of layers of woven fiber and/or knitted fiber. As the porous sheet 30, for example, a material similar to wiping cloth for use in a clean environment such as clean room, which produces less dust, can be suitably used. Fiber which can be a constituent of the porous sheet 30 can be made of, for example, a polyamide synthetic resin, polyester, ethylene tetrafluoride, or glass. The diameter of the fiber can be, for example, about 0.01-100 μm. A structure formed by such fiber can improve the design flexibility as to the porosity and the average pore diameter and therefore facilitate production of a porous sheet capable of suppressing occurrence of color unevenness attributable to a foreign object. Note that ethylene tetrafluoride is also referred to as polytetrafluoroethylene (PTFE). A sheet-like filter which is made of PTFE (thickness: e.g., 0.5-1.0 mm, porosity: about 55-75%) is excellent in flexibility and elasticity and thus can be suitably used as the porous sheet 30.

The porous sheet 30 of the embodiment of the present disclosure is not limited to this example. For example, the porous sheet 30 may be a film which includes a plurality of organic fillers and a resin binding the plurality of organic fillers. The resin is, for example, polypropylene. The porous sheet 30 may have a configuration realized by binding together a large number of particles with a resin so long as the porous sheet 30 has pores which have such a size that they can suck in the foreign object.

Since the porous sheet 30 is often used in a dry clean room, the porous sheet 30 is likely to be charged with static electricity if the porous sheet 30 is made only of an insulative material. When the problem of static electricity is to be avoided, it is desirable that an electrical conductor layer of not less than 5 nm and not more than 20 nm in thickness is provided on a surface of the porous sheet 30, specifically on a surface of fibers, particles, or resins which are constituents of the porous sheet 30. The presence of such an electrical conductor layer can suppress generation of static electricity.

Again, refer to FIG. 2. The foreign object 60 attached to the lower surface of the flexible substrate 12 is sucked into and held in the porous sheet 30 as a result of suction by the vacuum chuck surface 22. Therefore, as the same porous sheet 30 is repeatedly used for inspection of a large number of flexible displays 10, a large number of foreign objects 60 are taken into the porous sheet 30. Thus, the porous sheet 30 has not only the function of inspecting the flexible displays 10 but also the function of performing cleaning. As the porous sheet 30 is repeatedly used, the porous sheet 30 takes in the foreign objects 60 and becomes “dirtier”. Thus, it is desirable that the porous sheet 30 is replaced with a new one at appropriate timings. The dirty porous sheet 30 containing a large number of foreign objects 60 can be restored to a reusable condition by washing the porous sheet 30 such that the foreign objects 60 are released.

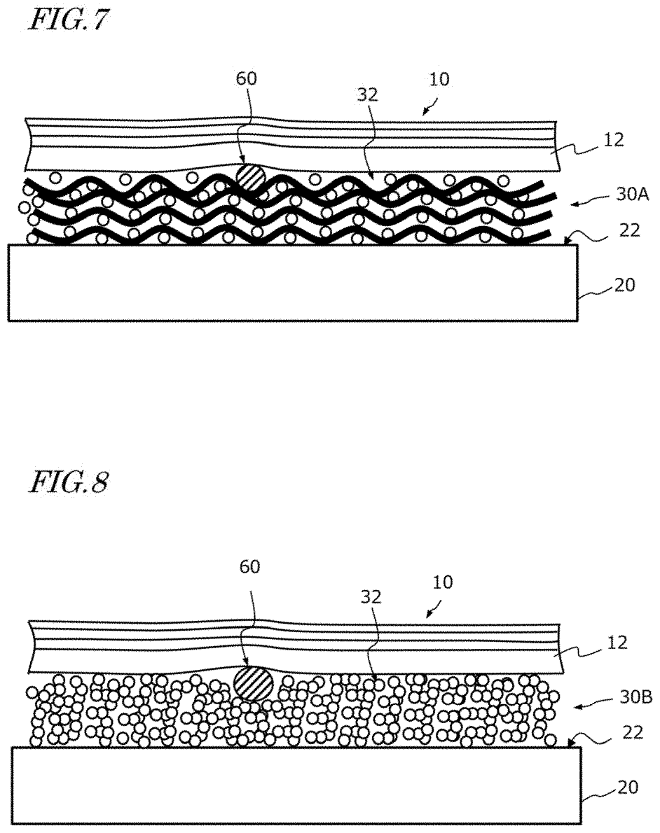

FIG. 7 is a cross-sectional view showing a porous sheet 30A which is a modification example of the porous sheet 30 shown in FIG. 2. The porous sheet 30A of this example includes a greater number of layers of woven fiber or knitted fiber and can suck in a greater foreign object 60.

FIG. 8 is a cross-sectional view showing a porous sheet 30B which is another modification example of the porous sheet 30. The porous sheet 30B of this example has a porous structure which does not contain fiber but a material in the form of particles flexibly bound together by a binder such as resin.

In the examples of FIG. 7 and FIG. 8, for the sake of simplicity, the adhesive layer provided on the vacuum chuck surface 22 is not shown. Also in these examples, a breathable adhesive layer 70 such as shown in FIG. 2 can be provided between the vacuum chuck surface 22 and the porous sheet 30A, 30B.

### INDUSTRIAL APPLICABILITY

An embodiment of the present invention provides a novel color unevenness inspection system for flexible devices. The flexible devices are broadly applicable to smartphones, tablet computers, on-board displays, and small-, medium-, and large-sized television sets.

### REFERENCE SIGNS LIST

10 . . . Flexible display, 20 . . . Inspection stage, 30 . . . Porous sheet, 40 . . . Supporting base, 50 . . . Imaging unit, 60 . . . Foreign object (such as particle), 70 . . . Breathable adhesive layer, 100 . . . Color unevenness inspection system

1. A color unevenness inspection system for inspecting a flexible display for color unevenness, the system comprising:
an inspection stage on which a flexible display including a flexible substrate is to be placed, the inspection stage having a vacuum chuck surface; and
a porous sheet placed on the vacuum chuck surface, the porous sheet being to be in contact with a lower surface of the flexible substrate,
wherein the porous sheet has a plurality of pores for sucking in a single or a plurality of foreign objects at the lower surface of the flexible substrate such that flatness of the lower surface is maintained.

2. The color unevenness inspection system of claim 1, wherein
a porosity of the porous sheet is not less than 50%, and
a thickness of the porous sheet is not less than three times a height of the foreign object.

3. The color unevenness inspection system of claim 2, wherein the thickness of the porous sheet is not less than 50 μm and not more than 5 mm.

4. The color unevenness inspection system of claim 1, wherein the porous sheet is a sheet including a single or a plurality of layers of woven fiber and/or knitted fiber.

5. The color unevenness inspection system of claim 1, wherein the porous sheet is a film containing a plurality of organic fillers and a resin which binds the plurality of organic fillers.

6. The color unevenness inspection system of claim 1, comprising an electrical conductor layer of not less than 5 nm and not more than 20 nm in thickness over a surface.

7. The color unevenness inspection system of claim 1, wherein the porous sheet is replaceably supported on the vacuum chuck surface of the inspection stage.

8. The color unevenness inspection system of claim 7, wherein a breathable adhesive layer is provided between the porous sheet and the vacuum chuck surface.

9. The color unevenness inspection system of claim 8, wherein the porous sheet includes the breathable adhesive layer that is in contact with the vacuum chuck surface.

10. The color unevenness inspection system of claim 8, wherein the breathable adhesive layer is located between at least part of the porous sheet on which the flexible display is to be placed and the vacuum chuck surface.

11. The color unevenness inspection system of claim 1, wherein an average pore diameter of the porous sheet is not more than 2 μm.
